(19) United States
(12) Patent Application Publication
(10) Pub. No.: US 2016/0079083 A1
(43) Pub. Date: Mar. 17, 2016

(54) SEMICONDUCTOR MANUFACTURING APPARATUS AND SEMICONDUCTOR MANUFACTURING METHOD

(71) Applicant: Kabushiki Kaisha Toshiba, Minato-ku (JP)

(72) Inventors: Mari KUSUNOKI, Yokkaichi (JP); Shinji MIYAZAKI, Mie (JP)

(73) Assignee: Kabushiki Kaisha Toshiba, Minato-ku (JP)

(21) Appl. No.: 14/608,748

(22) Filed: Jan. 29, 2015

(30) Foreign Application Priority Data
Sep. 11, 2014 (JP) 2014-185564

(51) Int. Cl. H01L 21/324; C23C 16/458; H01L 21/285; C23C 16/46; H01L 21/67; H01L 21/02

(52) U.S. Cl. CPC H01L 21/324; H01L 21/67115; H01L 21/67109; H01L 21/02271; H01L 21/0262; H01L 21/28556; C23C 16/46; C23C 16/4586

(57) ABSTRACT

According to an embodiment, a semiconductor manufacturing apparatus includes a chamber, a process tube, a substrate supporting portion, a heater, and a reflection plate. The heater is provided under the substrate supporting portion, and heats the substrates. The reflection plate is provided at a lower side of the heater, and reflects heat emitted from the heater upward.

### CROSS-REFERENCE TO RELATED APPLICATIONS

This application is based upon and claims the benefit of priority from Japanese Patent Application No. 2014-185564, filed on Sep. 11, 2014; the entire contents of which are incorporated herein by reference.

### FIELD

Embodiments described herein relate to a semiconductor manufacturing apparatus and a semiconductor manufacturing method.

### BACKGROUND

As a semiconductor manufacturing apparatus that grows a crystal film on a semiconductor substrate by vapor phase epitaxy, a batch type semiconductor manufacturing apparatus is known in which deposition process is performed collectively on a plurality of substrates provided horizontally in multilayers in a process tube. In this batch type semiconductor manufacturing apparatus, a temperature difference depending on positions where the substrates are arranged causes variation in thickness of films to be formed the substrates. In the semiconductor manufacturing apparatus, a heater that controls a temperature in a chamber is provided.

The heater is configured of a main heater that heats entireties of the plurality of substrates, an auxiliary heater that auxiliary heats substrates arranged on a top side, and an auxiliary heater that auxiliary heats substrates arranged on a bottom side. However, when accuracy demand for the film thickness becomes strict, it is difficult to highly accurately perform soaking control on the plurality of substrates merely by the temperature control of the plurality of heaters.

### BRIEF DESCRIPTION OF THE DRAWINGS

FIG. 1 is a schematic cross sectional diagram illustrating a configuration example of a semiconductor manufacturing apparatus of a first embodiment;

FIG. 2 is a diagram illustrating a temperature distribution in a substrate supporting portion;

FIG. 3 is a cross sectional diagram illustrating an internal configuration example of a bottom heater;

FIG. 4 is a cross sectional diagram illustrating an internal configuration example of a bottom heater; and

FIG. 5 is a schematic cross sectional diagram illustrating a configuration example of a semiconductor manufacturing apparatus of a second embodiment.

### DETAILED DESCRIPTION

According to the present embodiments, a semiconductor manufacturing apparatus includes a chamber, a process tube, a substrate supporting portion, a heater, and a reflection plate. The process tube is provided in the chamber, and reactant gas is introduced therein. The substrate supporting portion is provided in the process tube, and horizontally supports a plurality of substrates in multilayers. The heater is provided under the substrate supporting portion, and heats the substrates. The reflection plate is provided at a lower side of the heater, and reflects heat emitted from the heater upward.

Hereinafter, a semiconductor manufacturing apparatus and a semiconductor manufacturing method according to embodiments will be described in detail with reference to the attached drawings. Note that these embodiments do not limit the present invention.

### FIRST EMBODIMENT

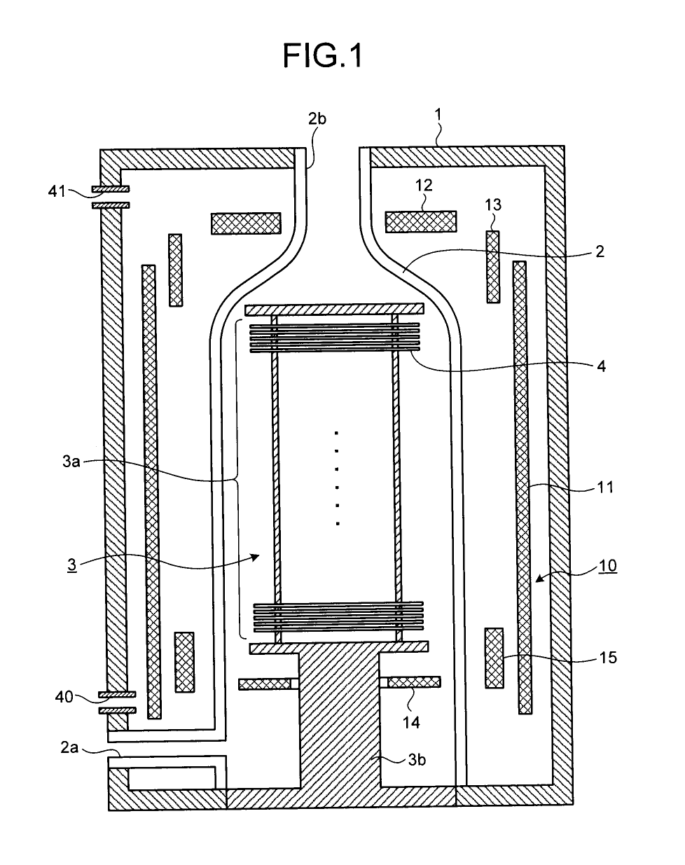

FIG. 1 is a schematic cross sectional diagram illustrating a schematic configuration of a semiconductor manufacturing apparatus according to the first embodiment. A batch type vertical heat treatment furnace as a semiconductor manufacturing apparatus includes a chamber 1, a process tube 2, a boat 3, and a heater 10. The semiconductor manufacturing apparatus grows crystal films on a plurality of substrates 4 by vapor phase epitaxy.

The process tube 2 is provided in the chamber 1. The process tube 2 configures a space in which reaction process using reactant gas is performed. The process tube 2 is configured for example using a transparent quartz member. The process tube 2 is provided with a gas inlet 2a and a gas outlet 2b. The reactant gas is introduced to the process tube 2 in the chamber 1 from the gas inlet 2a. The reactant gas introduced into the process tube 2 is discharged to outside of the chamber 1 from the gas outlet 2b.

The boat 3 is provided inside the process tube 2. The boat 3 includes a pedestal 3b and a substrate supporting portion 3a, and a plurality of substrate 4. The substrates 4 are set on the substrate supporting portion 3a. The boat 3 can move up and down, and is installed to the inside of the process tube 2 from the lower side of the process tube 2. The pedestal 3b is installed with a motor, and rotates the substrate supporting portion 3a by rotation of the motor. The substrate supporting portion 3a includes a multiple shelf structure in which the plurality of substrates 4 in a horizontal posture can be mounted. The substrate supporting portion 3a stacks the plurality of substrates 4 in an up and down direction at predetermined intervals.

The heater 10 is configured of five units, namely a main heater 11, a top heater 12, a top auxiliary heater 13, a bottom heater 14, and a bottom auxiliary heater 15. The main heater 11, the top heater 12, the top auxiliary heater 13, and the bottom auxiliary heater 15 are disposed between the process tube 2 and the chamber 1, and are disposed all-around of the process tube 2. The bottom heater 14 is provided inside the process tube 2, on a lower side of the substrate supporting portion 3a.

These main heater 11, top heater 12, top auxiliary heater 13, bottom heater 14, and bottom auxiliary heater 15 are configured of optical heating type heaters. The optical heating type heaters are for example carbon wire heaters.

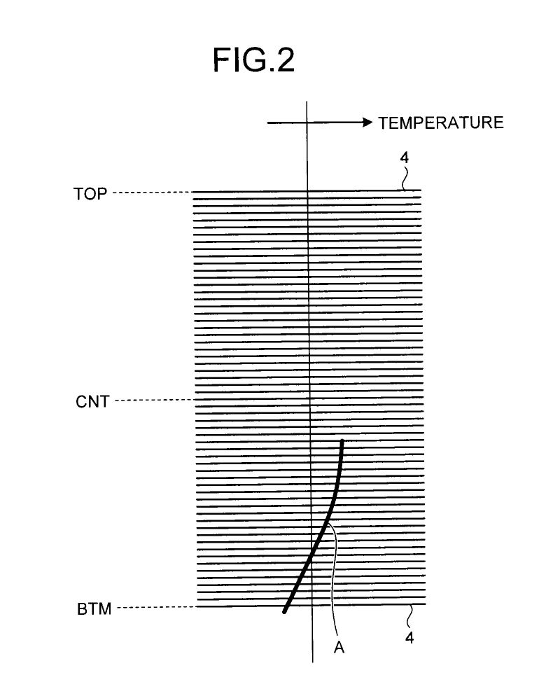

Here, as shown in FIG. 2, a center in the up and down direction of the substrate supporting portion 3a will be termed a center portion CNT, an upper end of the substrate supporting portion 3a will be termed a top portion TOP, and a lower end of the substrate supporting portion 3a will be termed a bottom portion BTM. The main heater 11 has a length in the up and down direction by which entire regions of the substrate supporting portion 3a in the up and down direction can be heated. The top heater 12 is arranged to heat the upper region of the substrate supporting portion 3a from above. The top auxiliary heater 13 is arranged to heat the upper region of the substrate supporting portion 3a from obliquely above. The bottom auxiliary heater 15 is arranged to heat the lower region of the substrate supporting portion 3a from obliquely below. The bottom heater 14 is arranged to heat the lower region of the substrate supporting portion 3a from underneath.

Gloss processing is performed on inner walls of the chamber 1, by which reflectivity with respect to beams from the main heater 11, the top heater 12, the top auxiliary heater 13, and the bottom auxiliary heater 15 is increased, and soaking performance in the chamber 1 is improved. The chamber 1 is provided with an air inlet 40 and an air outlet 41. Air taken in from the air inlet 40 is circulated in the chamber 1 and is discharged from the air outlet 41 to forcefully cool the main heater 11, the top heater 12, the top auxiliary heater 13, and the bottom auxiliary heater 15 in the chamber 1.

In the semiconductor manufacturing apparatus, the deposition process is collectively performed on the plurality of substrates 4 by supplying the reactant gas into the process tube 2, and heating the plurality of substrates 4 that is supported by the substrate supporting portion 3a by the heater 10.

In a semiconductor manufacturing apparatus with such a structure, a lateral surface side and an upper side of the process tube 2 are covered by the chamber 1 to the inner walls of which the gloss processing is performed. However, due to movement of the boat 3, a lower side of the process tube 2, that is, on a side that is right below the bottom heater 14, is not covered by the gloss-processed chamber 1. Further, due to a characteristic of heat, heating efficiency on a bottom side is inferior compared to a top side. Due to this, as shown in FIG. 2, a temperature of a region near the bottom portion BTM becomes low compared to a temperature of a region near the center portion CNT merely by the heating control by the main heater 11, the bottom heater 14, and the bottom auxiliary heater 15.

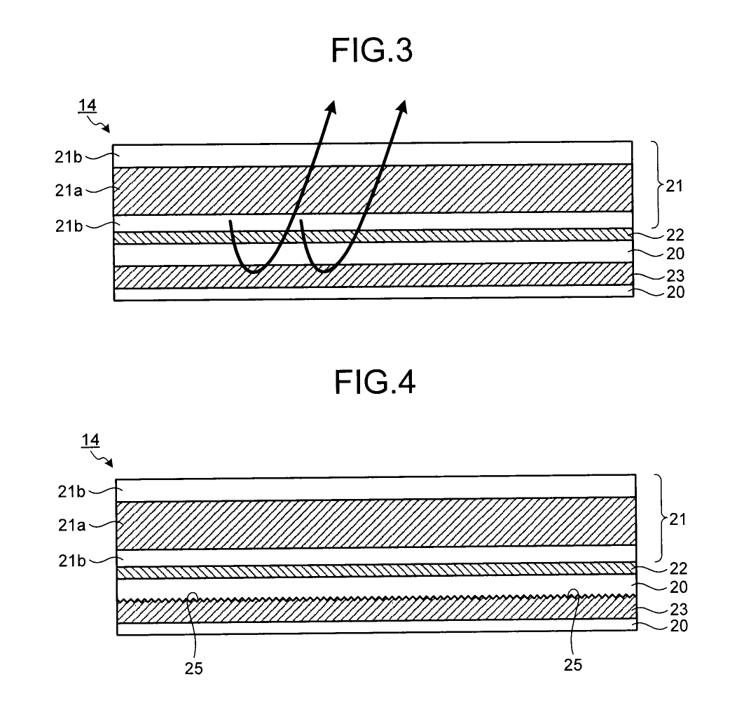

Thus, in the first embodiment, a reflection plate that heats the substrates 4 by reflecting heat emitted from the bottom heater 14 upward is provided on the lower side of the bottom heater 14. Specifically, a reflection plate 23 is provided in the bottom heater 14, and the heating efficiency of the region near the bottom portion BTM is improved. FIG. 3 shows an internal structure of the bottom heater 14. In the bottom heater 14, a carbon wire heater 21, a partitioning plate 22, the reflection plate 23 are sealed with respect to a flat plate body 20 configured of transparent quartz. That is, the carbon wire heater 21 and the reflection plate 23 are provided inside the process tube 2 as a unit integrated within the plate body 20. The carbon wire heater 21 that is a wire-shaped optical heating element is sealed on an upper portion side of the plate body 20. The carbon wire heater 21 is configured of a heater body 21a, and tubes 21b surrounding the heater body 21a and configured of transparent quartz. The carbon wire heater 21 is a planar heater formed in a suitable shape such as a spiral, and optically generates heat by electric conduction.

The reflection plate 23 is sealed on a lower portion side of the plate body 20, and light from the carbon wire heater 21 is reflected by the reflection plate 23 upward, as shown by an arrow. As the reflection plate 23, a single crystal silicon plate such as a wafer, or porous silicon is used. The reflection plate 23 may be provided flatly on an entire surface, or may be arranged corresponding to a portion where the carbon wire heater 21 is provided. With the reflection plate 23 being arranged, heat is prevented from escaping to a direction of a lower portion of the bottom heater 14, and the heating efficiency of the region near the bottom portion BTM can be improved.

The partitioning plate 22 is provided for insulation of the carbon wire heater 21 and the reflection plate 23, and defogging of the reflection plate 23. The partitioning plate 22 is configured for example of a transparent quartz plate.

FIG. 4 shows a modified example of the bottom heater 14. In the bottom heater 14 shown in FIG. 4, projections and recesses 25 are formed on an upper surface of the reflection plate 23, and a reflecting direction (reflecting angle) of reflected light is adjusted by the projections and recesses 25.

Accordingly, in the first embodiment, since the reflection plate 23 that reflects the light from the carbon wire heater 21 upward is sealed in the bottom heater 14, the heat is prevented from escaping to the direction of the lower portion of the bottom heater 14, and the heating efficiency of the region near the bottom portion BTM can be improved.

### SECOND EMBODIMENT

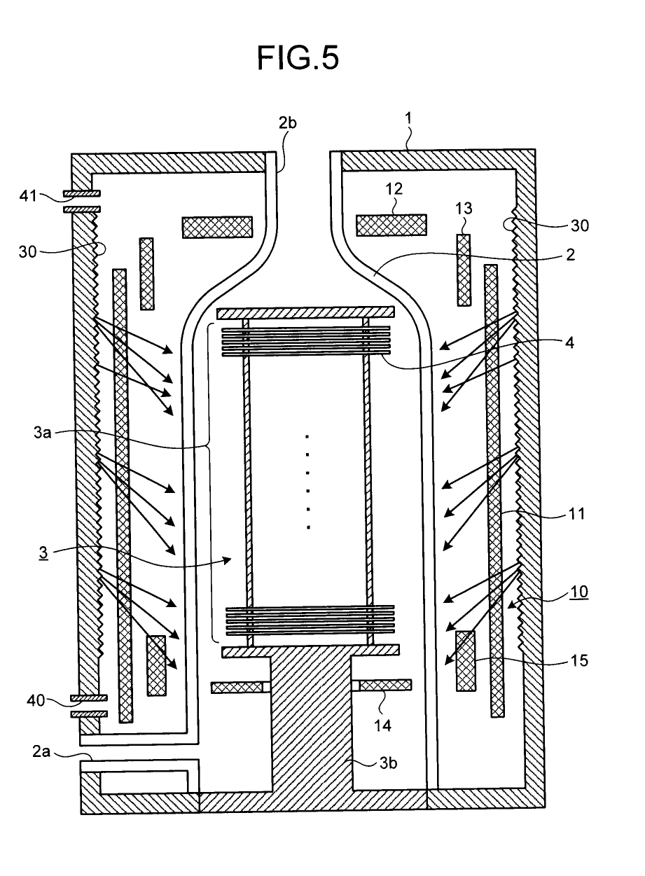

FIG. 5 is a schematic cross sectional diagram illustrating a schematic configuration of a semiconductor manufacturing apparatus according to the second embodiment. In the second embodiment, projections and recesses 30 that reflect light from a heater 10 with directivity with respect to a predetermined substrate region supported by the substrate supporting portion 3a is provided on inner walls of a chamber 1 to which gloss processing is performed. In this embodiment, as shown by an arrow, the projections and recesses 30 reflect the light from the heater 10 with obliquely downward directivity. Due to this, in the second embodiment, heating efficiency of a region near a bottom portion BTM can further be improved. Accordingly, a heat treatment furnace that can address more strict temperature demands and film thickness demands can be provided.

While certain embodiments have been described herein, these embodiments have been presented by way of example only, and are not intended to limit the scope of the present invention. Indeed, the novel embodiments described herein may be embodied in a variety of other embodiments; furthermore, various omissions, substitutions and changes in the form of the embodiments described herein may be made without departing from the spirit of the invention. The accompanying claims and their equivalents are intended to cover such embodiments or modifications as would fall within the scope and spirit of the invention.

What is claimed is:

1. A semiconductor manufacturing apparatus comprising:
a chamber;
a process tube that is provided in the chamber, and into which reactant gas is introduced;
a substrate supporting portion that is provided in the process tube, and horizontally supports a plurality of substrates in multilayers;
a heater that is provided under the substrate supporting portion, and heats the substrates; and
a reflection plate that is provided at a lower side of the heater, and reflects heat emitted from the heater upward.

2. The semiconductor manufacturing apparatus according to claim 1, wherein the reflection plate includes silicon.

3. The semiconductor manufacturing apparatus according to claim 1, wherein the heater is an optical heating heater,
the reflection plate reflects light emitted from the optical heating heater, and heats the substrates.

4. The semiconductor manufacturing apparatus according to claim 3, wherein projections and recesses are formed on a surface of the reflection plate on a side at which the heater is disposed.

5. The semiconductor manufacturing apparatus according to claim 3, wherein the heater and the reflection plate are provided inside the process tube as a unit integrated within a plate.

6. The semiconductor manufacturing apparatus according to claim 5, wherein a quartz plate is provided between the heater and the reflection plate.

7. The semiconductor manufacturing apparatus according to claim 1, further comprising a heater around the substrate supporting portion in the chamber,
wherein projections and recesses are formed on a lateral inner wall of the chamber.

8. The semiconductor manufacturing apparatus according to claim 7, wherein the projections and recesses reflect, to a predetermined substrate region supported by the substrate supporting portion, heat from the heater provided around the substrate supporting portion with directivity.

9. A semiconductor manufacturing apparatus comprising:
a chamber;
a process tube that is provided in the chamber, and into which reactant gas is introduced;
a substrate supporting portion that is provided in the process tube, and horizontally supports a plurality of substrates in multilayers;
a first heater that is provided between the process tube and the chamber, and heats the substrates;
a second heater that is provided under the substrate supporting portion, and heats the substrates; and
a reflection plate that is provided at a lower side of the second heater, and reflects heat emitted from the second heater upward.

10. The semiconductor manufacturing apparatus according to claim 9, wherein the second heater is provided inside the process tube.

11. The semiconductor manufacturing apparatus according to claim 9, wherein
the first heater is provided around the substrate supporting portion, and
comprises:
a third heater that heats an upper end portion to a lower end portion of the substrate supporting portion;
a fourth heater that heats an upper region within the substrate supporting portion; and
a fifth heater that heats a lower region within the substrate supporting portion.

12. The semiconductor manufacturing apparatus according to claim 9, wherein a lateral inner wall of the chamber is gloss processed.

13. The semiconductor manufacturing apparatus according to claim 9, wherein a lower side of the reflection plate is not covered by the chamber.

14. The semiconductor manufacturing apparatus according to claim 9, wherein the reflection plate includes silicon.

15. The semiconductor manufacturing apparatus according to claim 9, wherein the first heater and the second heater are an optical heating heater, and the reflection plate reflects light emitted from the optical heating heater, and heats the substrates.

16. The semiconductor manufacturing apparatus according to claim 15, wherein the optical heating heater is a carbon wire heater.

17. The semiconductor manufacturing apparatus according to claim 9, wherein a quartz plate is provided between the second heater and the reflection plate.

18. The semiconductor manufacturing apparatus according to claim 15, wherein projections and recesses are formed on a surface of the reflection plate on a side at which the second heater is disposed.

19. The semiconductor manufacturing apparatus according to claim 12, wherein projections and recesses are formed on the lateral inner wall of the chamber.

20. A semiconductor manufacturing method comprising:
introducing reactant gas to a process tube provided in a chamber;
horizontally supporting a plurality of substrates in multilayers on a substrate supporting portion in the process tube;
heating the substrates by a heater provided under the substrate supporting portion; and
reflecting heat emitted from the heater upward by a reflection plate provided at a lower side of the heater.
